(19) United States
(12) Patent Application Publication
(10) Pub. No.: US 2012/0231591 A1
(43) Pub. Date: Sep. 13, 2012

(54) METHODS FOR FABRICATING CMOS INTEGRATED CIRCUITS HAVING METAL SILICIDE CONTACTS

(75) Inventors: Stefan FLACHOWSKY, Dresden (DE); Ralf ILLGEN, Dresden (DE); Ina OSTERMAY, Coswig (DE); Jan HOENTSCHEL, Dresden (DE)

(73) Assignee: GLOBALFOUNDRIES INC., Grand Cayman (KY)

(21) Appl. No.: 13/045,666

(22) Filed: Mar. 11, 2011

(51) Int. Cl. H01L 21/8238; H01L 21/20

(52) U.S. Cl. 438/231; 438/478; 257/E21.632; 257/E21.09

(57) ABSTRACT

Methods are provided for fabricating CMOS integrated circuits. In accordance with one embodiment the methods include forming a gate electrode structure overlying an N-doped portion of a semiconductor substrate and growing an embedded silicon germanium area in the N-doped portion in alignment with the gate electrode structure. A layer of silicon is selectively grown overlying the embedded silicon germanium area and a nickel silicide contact is made to the layer of silicon.

### TECHNICAL FIELD

The present invention generally relates to methods for fabricating CMOS integrated circuits, and more particularly relates to methods for fabricating CMOS integrated circuits having metal silicide contacts without defects in the metal silicide.

### BACKGROUND

The majority of present day integrated circuits (ICs) are implemented by using a plurality of interconnected field effect transistors (FETs) also called metal oxide semiconductor field effect transistors (MOSFETs), or simply MOS transistors. Indeed, most ICs are complementary MOS (CMOS) circuits that use both P channel MOS (PMOS) transistors and N channel MOS (NMOS) transistors.

The trend in IC fabrication is to incorporate more and more circuitry on a single IC chip and to simultaneously improve the performance of the circuit. To achieve the performance goals, manufacturers have turned to techniques that apply strain to the individual transistors. Properly applied strain can be used to increase the mobility of majority carriers (holes for a PMOS transistor and electrons for an NMOS transistor) in the channel of an MOS transistor. One way to provide the proper strain is to form dual stress layers (DSL), sometimes also called “dual stress liners” overlying the transistors. Tensile stress layers are formed over NMOS transistors and compressive stress layers are formed over PMOS transistors. The mobility of holes in the channel of PMOS transistors can be further increased by embedding silicon germanium at the ends of the channel to impart a compressive strain on the channel. Further improvements in performance can be achieved by reducing time delays by reducing contact resistance, for example between source or drain regions and associated interconnect metallization. Contact resistance can be reduced by forming metal silicide contacts on the source and drain regions. Unfortunately the combination of dual stress layers, embedded silicon germanium, and metal silicide contacts has led to a significant morphological degradation of the metal silicide which manifests itself as voids in the metal silicide. These voids can lead to significant yield reduction.

Accordingly, it is desirable to provide methods for fabricating high performance and high yielding CMOS integrated circuits. In addition, it is desirable to provide methods for fabricating high yielding CMOS integrated circuits that incorporate dual stress liners, embedded silicon germanium, and metal silicide contacts. Furthermore, other desirable features and characteristics of the present invention will become apparent from the subsequent detailed description and the appended claims, taken in conjunction with the accompanying drawings and the foregoing technical field and background.

### BRIEF SUMMARY

Methods are provided for fabricating CMOS integrated circuits. In accordance with one embodiment the methods include forming a gate electrode structure overlying an N-doped portion of a semiconductor substrate and growing an embedded silicon germanium area in the N-doped portion in alignment with the gate electrode structure. A layer of silicon is selectively grown overlying the embedded silicon germanium area and a nickel silicide contact is made to the layer of silicon.

In accordance with a further embodiment, methods for fabricating a CMOS integrated circuit include forming a P-type region and an N-type region in a silicon substrate. A first gate electrode structure is formed overlying the P-type region and a second gate electrode structure is formed overlying the N-type region. A recess is etched in the N-type region in alignment with the second gate electrode structure and embedded silicon germanium is grown in the recess. N-type source and drain regions are ion implanted in the P-type region in alignment with the first gate electrode structure and P-type source and drain regions are ion implanted in the N-type region in and through the embedded silicon germanium in alignment with the second gate electrode structure. A silicon layer is grown overlying the P-type source and drain regions and a layer including nickel is deposited to form nickel silicide contacts to the N-type source and drain regions and to the P-type source and drain regions. A tensile insulating layer is formed overlying the P-type region and a compressive insulating layer is formed overlying the N-type region. Metallic contacts are formed to the nickel silicide contacts.

In accordance with yet another embodiment a method is provided for fabricating a CMOS integrated circuit that includes etching a recess extending into a silicon substrate and filling the recess with silicon germanium grown by a process of selective epitaxial growth. A layer of silicon is grown overlying the silicon germanium also by a process of selective epitaxial growth and a layer that includes a silicide forming metal is deposited overlying the layer of silicon. The layer that includes a silicide forming metal is heated to react the metal with the layer of silicon to form a metal silicide, the metal silicide having a thickness to consume substantially all the layer of silicon. A layer of tensile insulating material is deposited overlying the metal silicide and is heated. A portion of the layer of tensile insulating material is removed and a layer of compressive insulating material is deposited. The method is completed by forming metallic contacts to the metal silicide.

### BRIEF DESCRIPTION OF THE DRAWINGS

The present invention will hereinafter be described in conjunction with the following drawing figures, wherein like numerals denote like elements, and wherein:

FIGS. 1-15 schematically illustrate, in cross section, a CMOS integrated circuit and method steps for its fabrication.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

Various steps in the manufacture of MOS transistors are well known and so, in the interest of brevity, many conventional steps will only be mentioned briefly herein or will be omitted entirely without providing the well known process details. Although the term “MOS transistor” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

In the standard process for fabricating stressed CMOS integrated circuits silicon germanium is embedded at the ends of the channel of PMOS transistors, nickel silicide (NiSi) contacts are formed on the source and drain regions of both the PMOS transistors, including on the embedded silicon germanium, and the NMOS transistors, and a dual stress layer (DSL) is formed overlying the IC. During the process for forming the DSL, a tensile insulating layer is deposited overlying both the PMOS transistor and the NMOS transistor including over the nickel silicide contacts. The tensile insulating layer is cured by ultra violet (uV) heating to drive off excess hydrogen and to thereby increase the stress generated by the layer. Analysis of the integrated circuit structure at this point in the fabrication process shows a significant morphological degradation of the nickel silicide contacts in the PMOS region which result in a large number of voids in the nickel silicide contacts. The voids can be of such large dimension that subsequently formed metallization extends partially or even completely through the silicide contact to the underlying impurity doped source and drain regions. Subsequent metallization extending even partially through the silicide contacts results in high Ohmic contact resistance or even open circuits to the affected source and drain regions or short circuits between two adjacent contacts through the underlying substrate. If processing of the integrated circuit is continued, the voids in the nickel silicide contacts lead to a large percentage of device failures.

The inventors have discovered that the morphological change and voids in the nickel silicide contacts result from the combination of the high temperature of the uV cure cycle of the tensile insulating layer, the stress associated with the tensile insulating layer overlying the NiSi contacts, and the presence of germanium in the embedded SiGe regions and incorporated into the NiSi contacts. During the formation of the nickel silicide contacts germanium from the eSiGe is incorporated into the silicide, so the silicide formed on the source and drain regions of the PMOS transistors is not as homogeneous as is the silicide formed on the source and drain regions of the NMOS transistors. The tensile stress insulating layer is in direct contact with the non-homogeneous NiSi contacts during the uV cure heat cycle and it is the stress from the tensile stress layer on the non-homogeneous NiSi contacts in combination with the high temperature that results in the formation of voids. The incidence of voids in the nickel silicide contacts can be reduced slightly by lowering either or both of the tensile insulating layer deposition and curing temperatures, although even doing the deposition and curing at 400° C. does not significantly reduce the problem but does degrade device performance.

FIGS. 1-15 illustrate schematically, in cross section, method steps designed and used to reduce the aforementioned problems during the fabrication of a CMOS integrated circuit (IC) 100 in accordance with various embodiments. Only two transistors, one NMOS 113 and one PMOS 111 are illustrated in the FIGURES although those of skill in the art will appreciate that a CMOS IC may include a large number of each type of device.

As illustrated in FIG. 1, fabrication of a CMOS integrated circuit 100 begins by providing a semiconductor substrate 102. The semiconductor substrate can be silicon, silicon admixed with germanium, or silicon admixed with other elements as is common in the semiconductor industry, and for convenience will hereinafter be referred to simply as either a semiconductor or silicon substrate. The substrate can be a bulk silicon wafer (as illustrated) or a silicon on insulator (SOI) structure. In a SOI structure semiconductor substrate 102 is a thin layer of monocrystalline semiconductor material supported by an insulating layer which, in turn, is supported by a supporting substrate. A PMOS region 104 is formed in one portion of semiconductor substrate 102 and an NMOS region 106 is formed in another portion. The two regions may be separated by an electrical isolation structure such as, for example, a shallow trench isolation (STI) structure 108. In an SOI structure the STI could extend through the semiconductor layer to the underlying insulating layer. The PMOS region is doped with N-type conductivity determining dopant impurities such as phosphorus or arsenic. The NMOS region is doped with P-type conductivity determining dopant impurities such as boron. The correct doping concentration and doping profile in each of the regions can be established, for example, by multiple ion implantations.

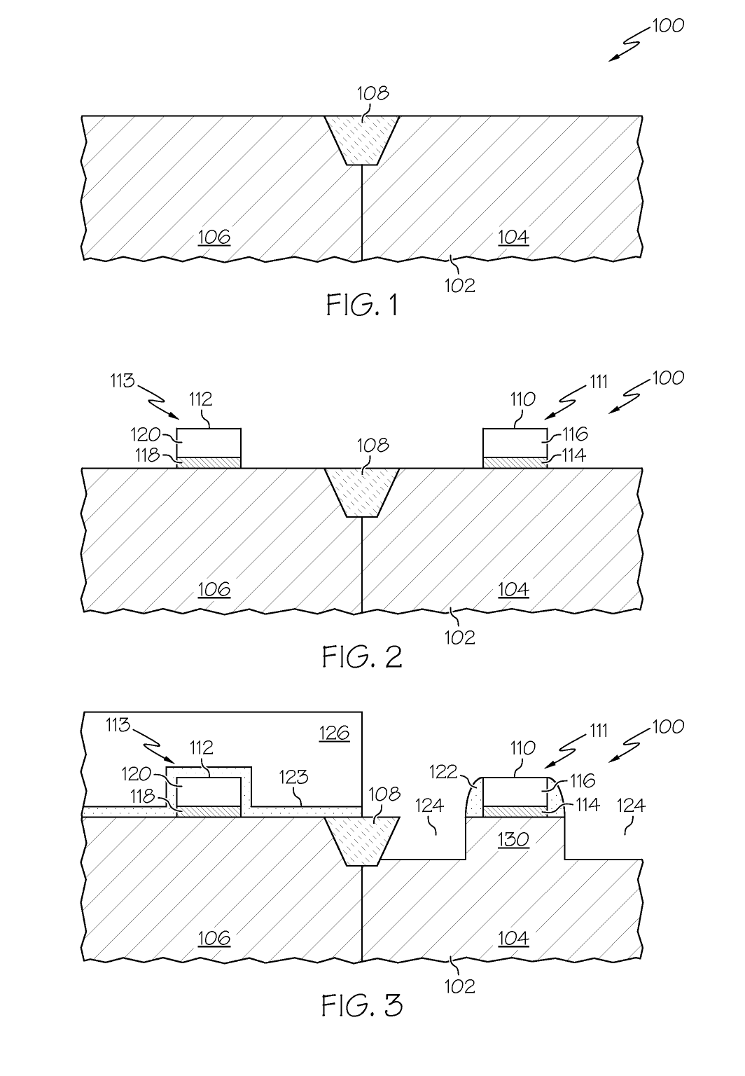

The fabrication of CMOS IC 100 continues as illustrated in FIG. 2 by forming a gate electrode structure 110 of a PMOS transistor 111 overlying PMOS region 104 and a gate electrode structure 112 of an NMOS transistor 113 overlying NMOS region 106. Gate electrode structure 110 includes a gate insulator 114 and a conductive gate electrode 116. Gate electrode structure 112 includes a gate insulator 118 and a conductive gate electrode 120. Gate insulators 114 and 118 can be silicon dioxide, a high dielectric constant insulator, other insulating material, or combinations thereof selected in accordance with the integrated circuit function being implemented. Gate insulators 114 and 118 can be, but need not necessarily be, the same material. Conductive gate electrodes 116 and 120 can be, for example, polycrystalline silicon, metal, other conductive material, or combinations thereof. Again, the materials selected for the conductive gate electrodes can be selected in accordance with the integrated circuit function being implemented. The two conductive gate electrodes can be the same or different materials.

As illustrated in FIG. 3, the fabrication of CMOS IC 100 continues, in accordance with one embodiment, by forming side wall spacers 122 on the side walls of gate electrode structure 110. The side wall spacers can be oxide, nitride, or other insulator, and can be formed by a blanket deposition of a layer of side wall spacer material 123 followed by an anisotropic etch process such as reactive ion etching (RIE). Although illustrated as a single side wall spacer, various process implementations may require one or more separate spacers. During the etching of the side wall spacers, the sidewall spacer material overlying NMOS region 106 can be protected from the anisotropic etch by a photolithographically pattered etch mask 126. The photolithographically patterned etch mask can be, for example, a patterned layer of deposited oxide or other insulating material. In accordance with this embodiment, recesses 124 are etched into PMOS region 104 using gate electrode structure 110 and its associated side wall spacers as etch masks. Photolithographically pattered etch mask 126 protects NMOS region 106 during the recess etch process.

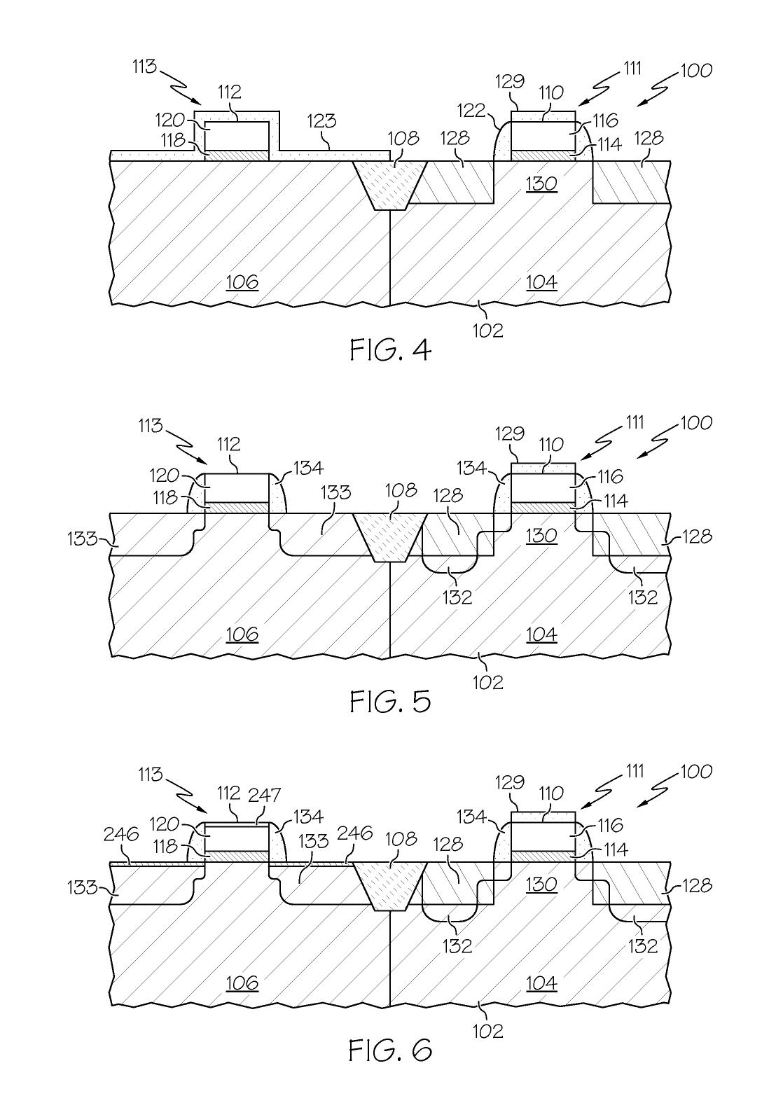

Following the etching of recesses 124 etch mask 126 is removed and the recesses are filled with embedded silicon germanium (eSiGe) 128 as illustrated in FIG. 4. The eSiGe can be grown by a process of selective epitaxial growth as is well known to those of skill in the art. In the selective epitaxial growth process the growth conditions are adjusted so that silicon germanium (SiGe) grows only on crystalline material. The crystalline material bounding recess 124 acts as a nucleation site for the growth of single crystalline silicon germanium. If conductive gate electrode 116 is polycrystalline silicon, the polycrystalline silicon acts as a nucleation site for the deposition of polycrystalline SiGe 129. Because the growth process is selective, no SiGe grows on insulating layers such as side wall spacers 122, the remaining portion of the side wall spacer material 123 overlying NMOS region 106, or on STI region 108.

The silicon germanium in recess 124 is aligned with gate electrode structure 110 and the channel region 130 of PMOS transistor 111 underlying the gate electrode structure. Silicon germanium has a larger lattice constant than the host silicon material and hence the eSiGe imparts a lateral compressive stress on the channel region. The lateral compressive stress on the channel of PMOS transistor 111 increases the mobility of majority carrier holes in that channel and thus serves to improve the performance of the transistor. Side wall spacers 122 and the remaining portion of side wall spacer material 123 are removed after the growth of eSiGe 128.

As illustrated in FIG. 5, source and drain regions are formed in alignment with gate electrode structures 110 and 112. The source and drain regions can be formed, for example, by ion implantation. For PMOS transistor 111 source and drain regions 132 can be formed by the implantation of boron ions into PMOS region 104 and into and through eSiGe 128. Similarly, source and drain regions 133 of NMOS transistor 113 can be formed by the implantation of phosphorus or arsenic ions into NMOS region 106. The source and drain regions typically include source and drain extensions formed by ion implantation using the gate electrode structures, often with thin side wall spacers (not shown) as implantation masks and deep source and drains formed by additional ion implantations using the gate electrode structures together with additional side wall spacers 134 as ion implantation masks. As before, side wall spacers can be formed by blanket depositing a layer of side wall spacer forming material and then etching by an anisotropic etch process. If semiconductor substrate 102 is a SOI substrate, the deep source and drains are typically designed to extend from the substrate surface to the underlying oxide layer. In addition to the source and drain extension ion implantations, halo implants (not illustrated) to tailor threshold voltage and punch through can be performed with the thin side wall spacers in place.

Heavy ion implants can also be performed on the source and drain regions and the gate electrode structure of NMOS transistor 113 to form an amorphous layer of silicon 246 at the surface of source and drain regions 133 and an amorphous layer of silicon 247 on conductive gate electrode 120 as illustrated in FIG. 6. The heavy ion implantation is performed using the same implant masking as is used during the halo implants into NMOS region 106. The implanted heavy ions can be, for example, xenon, argon, or silicon. The bombardment of the surface of substrate 102 with heavy ions and specifically the surface of NMOS region 106 disrupts the crystalline lattice of the implanted portion of the substrate causing the implanted portion to become amorphous. Forming an amorphous layer of silicon is useful in reducing floating body effects but, as will be explained below, has an added benefit for the process being described. During the various ion implantation steps, portions of IC 100 that are not intended to be implanted are protected by a patterned ion implantation mask such as a patterned layer of photoresist.

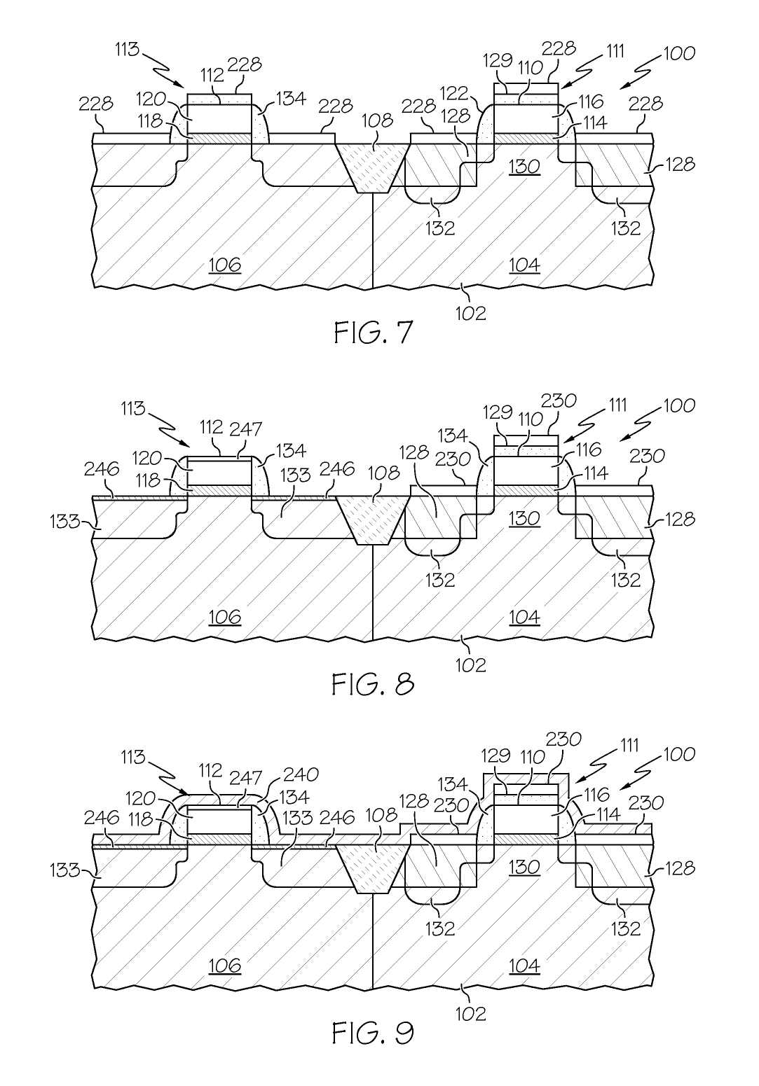

As illustrated in FIG. 7, the method in accordance with one embodiment continues by epitaxially growing a layer of undoped silicon 228 by a process of selective epitaxial growth. If an amorphous layer of silicon 246 and 247 has not been formed on source and drain regions 133 and conductive gate electrode 120, the layer of undoped silicon is formed overlying NMOS region 106 and PMOS region 104, including overlying eSiGe 128. Because the layer of undoped silicon 228 is grown by a process of selective epitaxial growth the layer of undoped silicon grows only on exposed crystalline material, namely eSiGe 128 in recess 124, SiGe 129 formed on gate electrode structure 110 and the source and drain regions and conductive gate electrode of NMOS transistor 113. The layer preferably has a thickness between about 5 nanometers (nm) and 15 nm for reasons to be explained below. Although layer 228 is undoped and potentially adds resistance to the contact to the source and drain regions, this potential problem is ameliorated by out diffusion of dopant impurities from the underlying source and drain regions which serves to dope the layer and to reduce its resistance. Alternatively, although not illustrated, the undoped silicon layer 228 can be grown before the ion implementation of source and drain regions 132 and 133. If grown before the doping of the source and drain regions the undoped silicon layer could then be impurity doped during the ion implement steps. This sequence of process steps has the advantage of doping the grown layer and reducing the resistance associated with a contact to the underlying source or drain region, but requires a change in the ion implementation doses and energies, especially in an IC fabricated on a SOI substrate, for forming, especially, the deep source and drain regions. For example, for forming a deep P-type source and drain of PMOS transistor 111, the implant energy is adjusted to increase the range of the implanted ions by an amount equal to the thickness of layer 228 so that the deep source and drain bottom out at the underlying insulator layer.

If an amorphous layer of silicon 246 and 247 has been formed on source and drain regions 133 and conductive gate electrode 120, the method in accordance with another embodiment continues by epitaxially growing a layer of P-doped silicon 230 by a process of selective epitaxial growth as illustrated in FIG. 8. Because layer of P-doped silicon 230 is grown by a process of selective epitaxial growth the silicon grows only on exposed crystalline material and not on amorphous material such as the amorphous layers 246 and 247. Again, the layer preferably has a thickness between about 5 nm and 15 nm. The layer grown overlying the source and drain regions and the conductive gate electrode of PMOS transistor 111 is impurity doped with P-type dopants so minimal resistance is added to any contact to those regions. The P-doped layer does not grow overlying the amorphous source and drain regions or the amorphous conductive gate electrode of NMOS transistor 113, so no added contact resistance is added to those regions.

Following the growth of undoped silicon layer 228 as illustrated in FIG. 7 or the growth of P-doped layer 230 illustrated in FIG. 8, the method in accordance with one embodiment continues as illustrated in FIG. 9 by the deposition of a metal silicide forming layer 240. FIG. 9 illustrates the metal silicide film deposited on the structure of FIG. 8, but those of skill in the art will understand that the same could be applied to the structure of FIG. 7. Metal silicide forming layer 240 can be, for example, a layer principally containing nickel and may hereinafter be referred to as a nickel layer. For convenience, but without limitation, metal silicides to be formed from the metal silicide forming layer may hereinafter be referred to as nickel silicides. Although referred to herein as “nickel silicide” or “NiSi”, it is not intended that those terms be limited to stoichiometric NiSi. Rather, the terms are intended to refer to the metal silicide commonly used in the semiconductor industry and all variations thereof including silicides that contain principally nickel as well as other metallic elements. Nickel layer 240 can be deposited, for example, by sputter deposition from a sputter target that is principally nickel admixed with platinum.

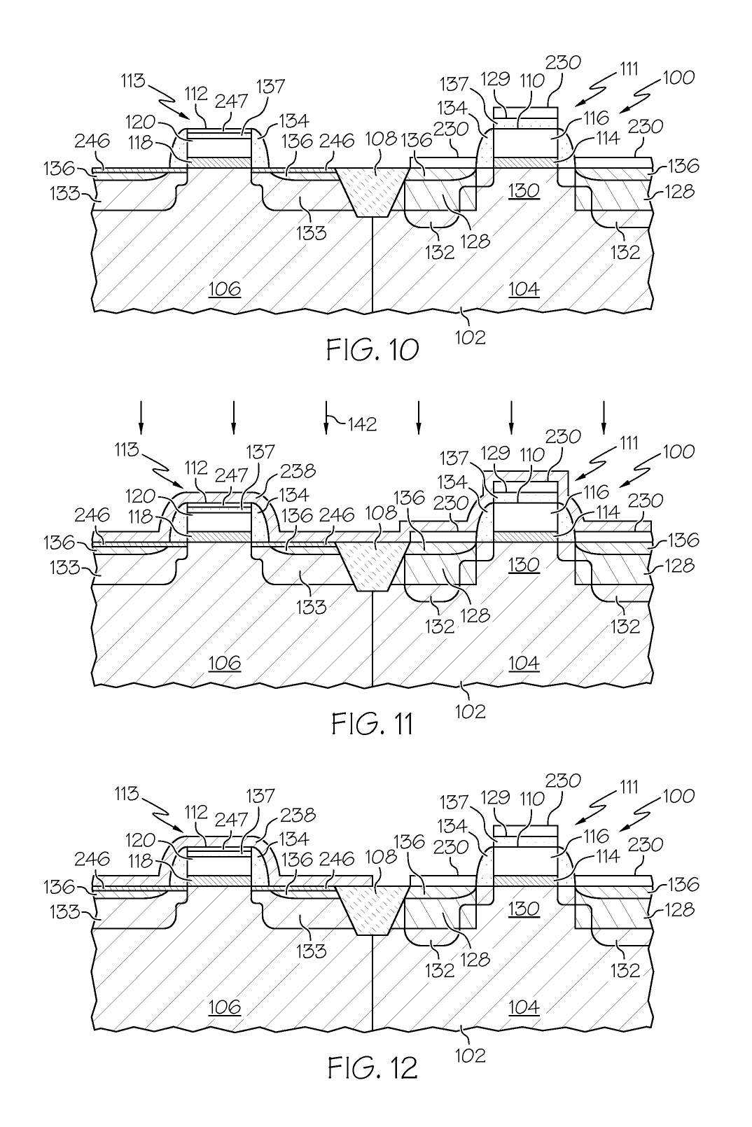

Nickel silicide contacts 136 are formed at the surface of the source and drain regions 132, 133 as illustrated in FIG. 10 by heating nickel layer 240 in a thermal cycle to react the nickel with exposed silicon to form the silicide. Ideally the thickness of metal silicide forming layer 240 and the thickness of undoped silicon layer 228 or of P-doped silicon layer 230 are selected so that during the thermal cycle the nickel layer reacts with and consumes substantially all of the undoped silicon layer or the P-doped silicon layer. Choosing the thicknesses in this manner avoids having either a lightly doped or undoped silicon layer adding undesired resistance to the contact to be made to the source and drain regions and also avoids incorporating germanium into the silicide being formed. The metal silicide contacts are used to reduce the contact resistance between the source and drain regions 132, 133 and subsequently formed metal contacts to those regions. NiSi contacts 137 also form on exposed polycrystalline or amorphous silicon on the conductive gate electrodes 120, 122.

FIGS. 11-14 illustrate method steps for forming dual stress layers (DSL) on integrated circuit 100. The DSL process is designed to result in a tensile stress layer 138 overlying NMOS transistor 113 and a compressive stress layer 140 overlying PMOS transistor 111. Tensile stress layer 138 enhances the mobility of majority carrier electrons in the channel of the NMOS transistor and compressive stress layer 140 further enhances the mobility of holes in channel 130 of the PMOS transistor.

As illustrated in FIG. 11, the DSL process begins by blanket depositing a tensile insulating later 238 overlying both the PMOS region 104 and the NMOS region 106, including overlying the gate electrode structures and the nickel silicide contacts. The tensile insulating layer can be, for example, a tensile silicon nitride layer deposited by a plasma enhanced chemical vapor deposition (PECVD) process. As is well known, process conditions and reactants are selected to cause the deposited nitride layer to be deposited as a tensile layer. The tensile insulating layer is typically deposited at a temperature between 400° C. and 480° C. Such a tensile silicon nitride layer deposited by a plasma enhanced deposition process may hereinafter be referred to as a “tensile plasma enhanced nitride” (TPEN) layer. The tensile insulating layer is cured to drive off excess hydrogen in the film and to increase the tensile stress in the film. The curing step can increase the stress in the layer by up to 50%, an increase in stress that cannot be achieved by deposition conditions alone. The curing step is conventionally done by ultraviolet (uV) radiation as illustrated at 142 to heat the film to between 400° C. and 480° C. Although not illustrated in the FIGURES, an etch stop layer may be deposited before the deposition of tensile insulating layer 238 and a further etch stop layer may be deposited overlying the tensile insulating layer, either before or after the curing step. The etch stop layers facilitate the pattering of both the tensile insulating layer and a subsequently deposited compressive insulating layer.

The DSL process continues as illustrated in FIG. 12 by patterning tensile insulating layer 238 to remove the portion of the tensile insulating layer overlying PMOS region 104. The remaining portion of the tensile insulating layer, now indicated by 138, overlies NMOS transistor 113 and NMOS region 106.

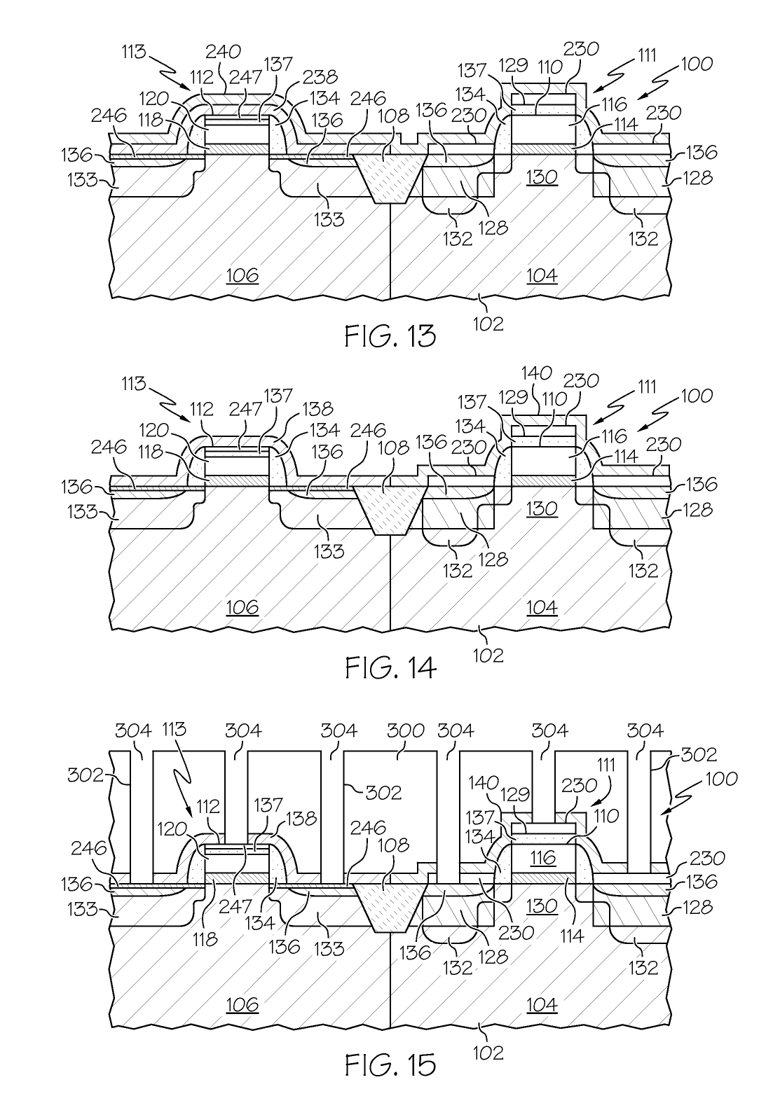

Following the patterning of tensile insulating layer 238 to leave a remaining portion 138 of the tensile insulating layer overlying the NMOS region, a compressive insulating layer 240 is blanket deposited overlying portion 138 of the tensile insulating layer and PMOS region 104 as illustrated in FIG. 13. The compressive insulating material layer can be, for example, a compressive layer of silicon nitride deposited by a PECVD process. Such a compressive silicon nitride layer deposited by a plasma enhanced deposition process may hereinafter be referred to as a “compressive plasma enhanced nitride” (CPEN) layer. As with the deposition of tensile insulating layer 238, the deposition conditions and reactants for depositing compressive insulating layer 240 can be adjusted to deposit a compressive layer.

The DSL process is completed as illustrated in FIG. 14 by removing a portion of the compressive insulating layer 240 overlying the remaining portion of the tensile insulating layer to leave a portion 140 of the compressive insulating layer overlying PMOS transistor 111 and PMOS region 104. Analysis of the integrated circuit structure at this point in the fabrication process shows no significant morphological degradation of the nickel silicide contacts in the PMOS region and no voids in the nickel silicide contacts.

After completing the formation of the dual stress layers, IC 100 is completed in the normal manner. In accordance with one embodiment, as illustrated in FIG. 15, a layer of insulator 300 is blanket deposited over the tensile and compressive insulating layers and is planarized, for example by CMP. Contact openings 302 are etched through the layer of insulator 300 and the respective underlying tensile insulating layer 138 and compressive insulating layer 140 to expose portions of nickel silicide contacts 136 and 137. Because there are no voids in the NiSi contacts, the contact etch stops on the NiSi and does not punch through deep into the underlying active silicon areas or into the conductive gate electrodes. The contact openings 302 are filled with metal or other conductive material to form conductive interconnects 304 making electrical contact to the nickel silicide contacts. Other back-end-of-line process steps can then follow as are needed to complete the circuit function being implemented.

While exemplary embodiments for fabricating a CMOS integrated circuit have been presented in the foregoing detailed description, it should be appreciated that a vast number of variations exist. It should also be appreciated that the exemplary embodiments are only examples, and are not intended to limit the scope, applicability, or configuration of the invention in any way. Rather, the foregoing detailed description will provide those skilled in the art with a convenient road map for implementing the exemplary embodiments. It should be understood that various changes can be made in the arrangement of elements as well as he process steps for achieving those elements without departing from the scope of the invention as set forth in the appended claims and the legal equivalents thereof.

What is claimed is:

1. A method for fabricating a CMOS integrated circuit comprising:
forming a gate electrode structure overlying an N-doped portion of a semiconductor substrate;
growing an embedded silicon germanium area in the N-doped portion in alignment with the gate electrode structure;
selectively growing a layer of silicon overlying the embedded silicon germanium area; and
forming a nickel silicide contact to the layer of silicon.

2. The method of claim 1 further comprising forming a second gate electrode structure overlying a P-doped portion of the semiconductor substrate.

3. The method of claim 2 further comprising:
depositing a tensile insulating layer overlying the N-doped portion and the P-doped portion including overlying the nickel silicide contacts;
removing a portion of the tensile insulating layer overlying the N-doped portion;
and depositing a layer of compressive insulating material.

4. The method of claim 1 further comprising implanting P-type conductivity determining ions to form source and drain regions in alignment with the gate electrode structure before selectively growing the layer of silicon.

5. The method of claim 4 wherein selectively growing a layer of silicon comprises selectively growing an undoped layer of silicon.

6. The method of claim 4 wherein selectively growing a layer of silicon comprises selectively growing a layer of silicon doped with P-type conductivity determining impurities.

7. The method of claim 1 further comprising implanting P-type conductivity determining ions in alignment with the gate electrode structure after selectively growing a layer of silicon.

8. The method of claim 7 wherein selectively growing a layer of silicon comprises growing a layer of silicon having a thickness of between about 5 nm and about 15 nm and wherein implanting P-type conductivity determining ions comprises implanting P-type conductivity determining ions at an implant energy adjusted to increase the range of the implanted ions by an amount substantially equal to the thickness of the layer of silicon.

9. The method of claim 1 further comprising:
depositing a layer of insulating material overlying the nickel silicide contact;
etching an opening extending through the layer of insulating material to expose a portion of the nickel silicide contact; and
forming a metallic contact extending through the opening to the nickel silicide contact.

10. A method for fabricating a CMOS integrated circuit comprising:
forming a P-type region and an N-type region in a silicon substrate;
forming a first gate electrode structure overlying the P-type region and a second gate electrode structure overlying the N-type region;
etching a recess in the N-type region in alignment with the second gate electrode structure;
growing embedded silicon germanium in the recess;
ion implanting N-type source and drain regions in the P-type region in alignment with the first gate electrode structure and P-type source and drain regions in the N-type region in and through the embedded silicon germanium in alignment with the second gate electrode structure;
growing a silicon layer overlying the P-type source and drain regions;
depositing a layer comprising nickel to form nickel silicide contacts to the N-type source and drain regions and to the P-type source and drain regions;
forming a tensile insulating layer overlying the P-type region and a compressive insulating layer overlying the N-type region; and
forming metallic contacts to the nickel silicide contacts.

11. The method of claim 10 wherein growing a silicon layer comprises growing a layer of undoped silicon.

12. The method of claim 10 further comprising implanting the N-type source and drain regions with ions to render the surface of the N-type source and drain regions amorphous and wherein growing a silicon layer comprises growing a layer of silicon doped with P-type conductivity determining impurities.

13. The method of claim 10 wherein growing a silicon layer comprises growing a silicon layer having a thickness between about 5 nm and about 15 nm and wherein depositing a layer comprising nickel comprises depositing a layer having sufficient nickel to react with the silicon layer and form nickel silicide contacts extending substantially through the thickness of the silicon layer.

14. The method of claim 10 wherein growing a silicon layer further comprises growing a silicon layer overlying the N-type source and drain regions, the first gate electrode structure and the second gate electrode structure.

15. A method for fabricating a CMOS integrated circuit comprising:
etching a recess extending into a silicon substrate;
filling the recess with silicon germanium grown by a process of selective epitaxial growth;
growing a layer of silicon overlying the silicon germanium by a process of selective epitaxial growth;
depositing a layer comprising a silicide forming metal overlying the layer of silicon;
heating the layer comprising a silicide forming metal to react the metal with the layer of silicon to form a metal silicide, the metal silicide having a thickness to consume substantially all of the layer of silicon;
depositing a layer of tensile insulating material overlying the metal silicide and heating the layer of tensile insulating material;
removing a portion of the layer of tensile insulating material and depositing a layer of compressive insulating material; and
forming metallic contacts to the metal silicide.

16. The method of claim 15 wherein growing a layer of silicon comprises growing a layer of undoped silicon.

17. The method of claim 15 wherein growing a layer of silicon comprises growing a layer of silicon doped with P-type conductivity determining impurities.

18. The method of claim 15 wherein growing a layer of silicon comprises growing a layer of silicon having a thickness between about 5 nm and about 15 nm.

19. The method of claim 15 wherein depositing a layer of tensile insulating material comprises depositing a layer of TPEN and wherein depositing a layer of compressive insulating material comprises depositing a CPEN layer.

20. The method of claim 15 wherein depositing a layer comprising a silicide forming metal comprises depositing a layer comprising nickel.
